(19) United States
(12) Patent Application Publication
(10) Pub. No.: US 2019/0204685 A1
(43) Pub. Date: Jul. 4, 2019

(54) BACKLIGHT UNIT FOR DISPLAY DEVICE, MANUFACTURING METHOD THEREOF, BACKLIGHT MODULE AND DISPLAY DEVICE

(71) Applicants: BEIJING BOE DISPLAY TECHNOLOGY CO., LTD., Beijing (CN); BOE TECHNOLOGY GROUP CO., LTD., Beijing (CN)

(72) Inventor: Yaohui WANG, Beijing (CN)

(21) Appl. No.: 16/047,075

(22) Filed: Jul. 27, 2018

(30) Foreign Application Priority Data
Jan. 2, 2018 (CN) 201810003149.3

(51) Int. Cl. G02F 1/1335; F21V 8/00; H01L 25/075

(52) U.S. Cl. CPC G02F 1/133608; H01L 25/0753; G02F 1/133603; G02B 6/009

(57) ABSTRACT

A backlight unit for a display device, a manufacturing method thereof, a backlight module, and a display device. The backlight unit includes a substrate on which at least one opening is disposed, and a light emitting diode embedded in the at least one opening. By embedding a light emitting diode in a substrate, the space occupation ratio of the thickness of the backlight unit can be effectively reduced. When applied to a display device, the distance between the light emitting diode and the display area of the display device can be effectively increased, which reduces light shadow or light leakage due to insufficient incident distance of the backlight unit in the display device, and improves the display quality of the display device.

### RELATED APPLICATIONS

The present application claims the benefit of Chinese Patent Application No. 201810003149.3, filed on Jan. 2, 2018, the entire disclosures of which are incorporated herein by reference.

### TECHNICAL FIELD

The present disclosure relates to the field of display technology, in particular to a backlight unit for a display device, a manufacturing method thereof, a backlight module and a display device.

### BACKGROUND

At present, a method for manufacturing a backlight unit used in a conventional frameless display device is to directly attach light emitting diodes (LEDs) to a substrate by soldering. The resulting backlight unit has a certain thickness so that the space occupied by the backlight unit is too large and the incident distance of the light source is affected. An insufficient incident distance of the light source may cause macroscopical light shadow and light leakage of the liquid crystal module, and the LEDs in the directly-attached backlight unit are exposed, making them vulnerable to damages caused by impacts.

### SUMMARY

In one embodiment of the present disclosure, the present disclosure provides a backlight unit for a display device. According to an embodiment of the present disclosure, the backlight unit for a display device includes: a substrate on which at least one opening is disposed; and a light emitting diode embedded in the at least one opening.

In some embodiments, the number of the at least one opening is greater than or equal to 2, and the at least one opening is evenly distributed in a long side direction of the substrate.

In some embodiments, each opening is provided with one light emitting diode.

In some embodiments, the light emitting diode includes a light emitting surface and a surface opposite to the light emitting surface, where he light emitting surface and a front surface of the substrate are located in a same plane.

In some embodiments, the light emitting diode includes a light emitting surface and a surface opposite to the light emitting surface, and the surface opposite to the light emitting surface is fixedly connected to a back surface of the substrate.

In some embodiments, the backlight unit further includes a protective layer covering the back surface of the substrate and the surface opposite to the light emitting surface.

In another embodiment of the present disclosure, the present disclosure provides a method for manufacturing a backlight unit for a display device. The method includes the steps of forming at least one opening in a substrate, and embedding a light emitting diode in the at least one opening.

In some embodiments, the light emitting diode includes a light emitting surface and a surface opposite to the light emitting surface, and the method further includes the step of arranging the light emitting surface and a front surface of the substrate in a same plane.

In some embodiments, the light emitting diode includes a light emitting surface and a surface opposite to the light emitting surface, and the method further includes the step of fixedly connecting the surface opposite to the light emitting surface to the back surface of the substrate.

In some embodiments, the method further includes the step of arranging a protective layer covering the back surface of the substrate and the surface opposite to the light emitting surface.

In yet another embodiment of the present disclosure, the present disclosure provides a backlight module. The backlight module includes the backlight unit as described in the above embodiments.

In some embodiments, the number of the at least one opening is greater than or equal to 2, and the at least one opening is evenly distributed in the long side direction of the substrate.

In some embodiments, each opening is provided with one light emitting diode.

In some embodiments, the light emitting diode includes a light emitting surface and a surface opposite to the light emitting surface; the light emitting surface and a front surface of the substrate are located in a same plane.

In some embodiments, the light emitting diode includes a light emitting surface and a surface opposite to the light emitting surface, and the surface opposite to the light emitting surface is fixedly connected to the back surface of the substrate.

In some embodiments, the backlight module further includes a protective layer covering the back surface of the substrate and the surface opposite to the light emitting surface.

In still another embodiment of the present disclosure, the present disclosure provides a display device. The display device includes the backlight module as described in the above embodiments.

In some embodiments, a distance between the light emitting surface of the light emitting diode of the backlight module and a display area of the display device ranges from 3.5 to 3.7 mm.

In some embodiments, the light emitting diode includes a light emitting surface and a surface opposite to the light emitting surface; the light emitting surface and a front surface of the substrate are located in a same plane.

In some embodiments, the light emitting diode includes a light emitting surface and a surface opposite to the light emitting surface, and the surface opposite to the light emitting surface is fixedly connected to the back surface of the substrate.

### BRIEF DESCRIPTION OF THE DRAWINGS

FIG. 1 illustrates a structural schematic diagram of a backlight module in the related art;

FIG. 2 illustrates a planar structural schematic diagram of a surface of a backlight unit facing a display area in the related art;

FIG. 3 illustrates a structural schematic diagram of a backlight unit in some embodiments of the present disclosure;

FIG. 4 illustrates a planar structural schematic diagram of a surface of a backlight unit facing a display area in some embodiments of the present disclosure;

FIG. 5 illustrates a planar structural schematic diagram of a surface of a backlight facing away from a display area in some embodiments of the present disclosure;

FIG. 6 illustrates a structural schematic diagram of a relative position of a backlight unit and a display area in some embodiments of the present disclosure;

FIG. 7a illustrates a structural schematic diagram of a cross section taken along line C-C′ in FIG. 6;

FIG. 7b illustrates a structural schematic diagram of a cross section taken along line A-A′ in FIG. 6;

FIG. 8 illustrates a structural schematic diagram of a relative position of a backlight unit and a display area in other embodiments of the present disclosure;

FIG. 9 illustrates a structural schematic diagram of a cross section taken along line B-B′ in FIG. 8; and

FIG. 10 illustrates a structural schematic diagram of a relative position of a backlight unit and a display area in other embodiments of the present disclosure.

### DETAILED DESCRIPTION OF THE DISCLOSURE

The embodiments of the present disclosure are described in detail below. The embodiments described below are exemplary. The embodiments are used to explain the present disclosure only, and should not be construed as limiting the present disclosure. For specific techniques or conditions that are not indicated in the embodiments, they are performed according to the techniques or conditions described in the literature in the field or according to the product specifications. The reagents or instruments used without indicating the manufacturers are all conventional products that can be purchased on the market.

The present disclosure aims to solve one of the technical problems in the related art at least to some extent. To this end, an object of the present disclosure is to provide a backlight unit for a display device, which has a small space occupation ratio, can effectively reduce light shadow and light leakage, and prevent light emitting diodes from being damaged by impacts.

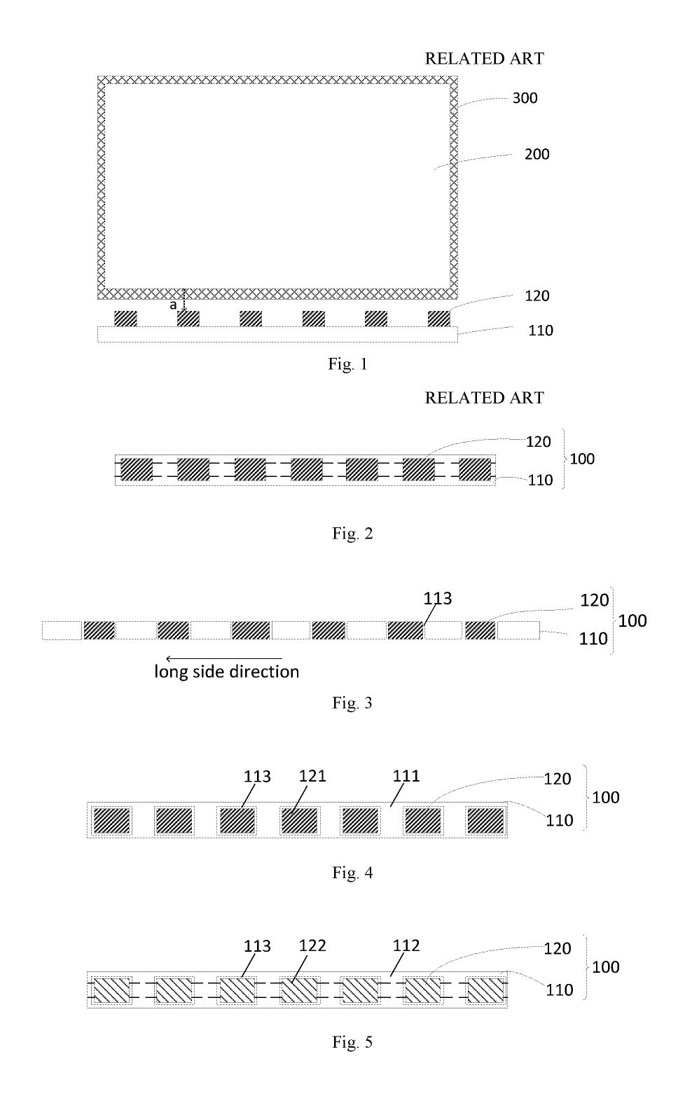

In the frameless display device of the related art, referring to FIG. 1 and FIG. 2, a backlight unit 100 is manufactured by directly attaching a light emitting diode 120 to a substrate 110 by soldering. The thickness of the backlight unit 100 has a large space occupation ratio, which affects the incident distance, causing macroscopical light shadow and light leakage; and the LEDs are exposed, making them vulnerable to damages caused by impacts. For the above problems, it is found that the light emitting diodes can be embedded into the substrate to reduce the space occupation ratio of the thickness of the backlight unit and increase the distance between the backlight unit and the display area, thereby increasing the incident distance. Thus, macroscopical light shadow and light leakage of the backlight module is reduced, and the display effect of the display device including the backlight unit is increased.

Based on the above, in an embodiment of the present disclosure, the present disclosure provides a backlight unit for a display device. According to an embodiment of the present disclosure, referring to FIG. 3, a backlight unit 100 for a display device includes: a substrate 110 on which at least one opening 113 is disposed; and a light emitting diode 120 embedded in the at least one opening 113.

It is found that by embedding a light emitting diode in a substrate, the space occupation ratio of the thickness of the backlight unit can be effectively reduced. When applied to a display device, the distance between the backlight unit and the display area of the display device can be effectively increased, thereby reducing light shadow or light leakage due to insufficient incident distance of the backlight unit in the display device and improving the display quality of the display device including the backlight unit. The backlight unit is particularly suitable for a frameless display device. By disposing the surface of the light emitting diode facing the display area and the surface of the substrate facing the display area in the same plane, the light emitting diode can be prevented from being damaged by impacts.

According to the embodiments of the present disclosure, the material of the substrate is not particularly limited as long as the heat dissipation requirements can be satisfied, and those skilled in the art can flexibly select the material of the substrate according to actual requirements. For example, the substrate may include, but is not limited to, an aluminum substrate, a copper substrate, an iron substrate, an epoxy-glass fiber cloth substrate, or an aluminum-ceramic composite substrate, etc. Thus, the structure of the substrate is simple and easy to be implemented, the material is varied, and the cost is low.

According to the embodiments of the present disclosure, the thickness of the substrate is not particularly limited as long as the space occupation ratio of the thickness is relatively small, and those skilled in the art can flexibly select the thickness of the substrate according to actual requirements. In some embodiments of the present disclosure, the thickness of the substrate can range from 0.6 to 0.8 mm. Therefore, the space occupation ratio of the substrate is small. By embedding the light emitting diode in the substrate, the incident distance of the backlight unit can be effectively increased and macroscopical light shadow and light leakage can be reduced.

According to the embodiments of the present disclosure, the shape of the light emitting diode is not particularly limited as long as the display requirements of the display device including the light emitting diode can be satisfied, and those skilled in the art can flexibly select the shape of the light emitting diode according to actual requirements. For example, the shape of the light emitting diode can include, but is not limited to, a circle or a polygon. Thus, the structure of the light emitting diode is simple and easy to be implemented, and the display requirements of the display device including the light emitting diode can be satisfied.

According to the embodiments of the present disclosure, the size of the light emitting diode is also not particularly limited as long as the display requirements of the display device including the light emitting diode can be satisfied, and those skilled in the art can flexibly select the size of the light emitting diode according to actual requirements. A size of a circular LED is used as an example to illustrate the size of the LED of the present disclosure: the size of the circular LED may be, but is not limited to, a diameter φ of 2 mm, 4.4 mm, 5 mm, 8 mm, 10 mm, or 20 mm, etc. Thus, the structure of the light emitting diode is simple and easy to be implemented, and the display requirements of the display device including the light emitting diode can be satisfied.

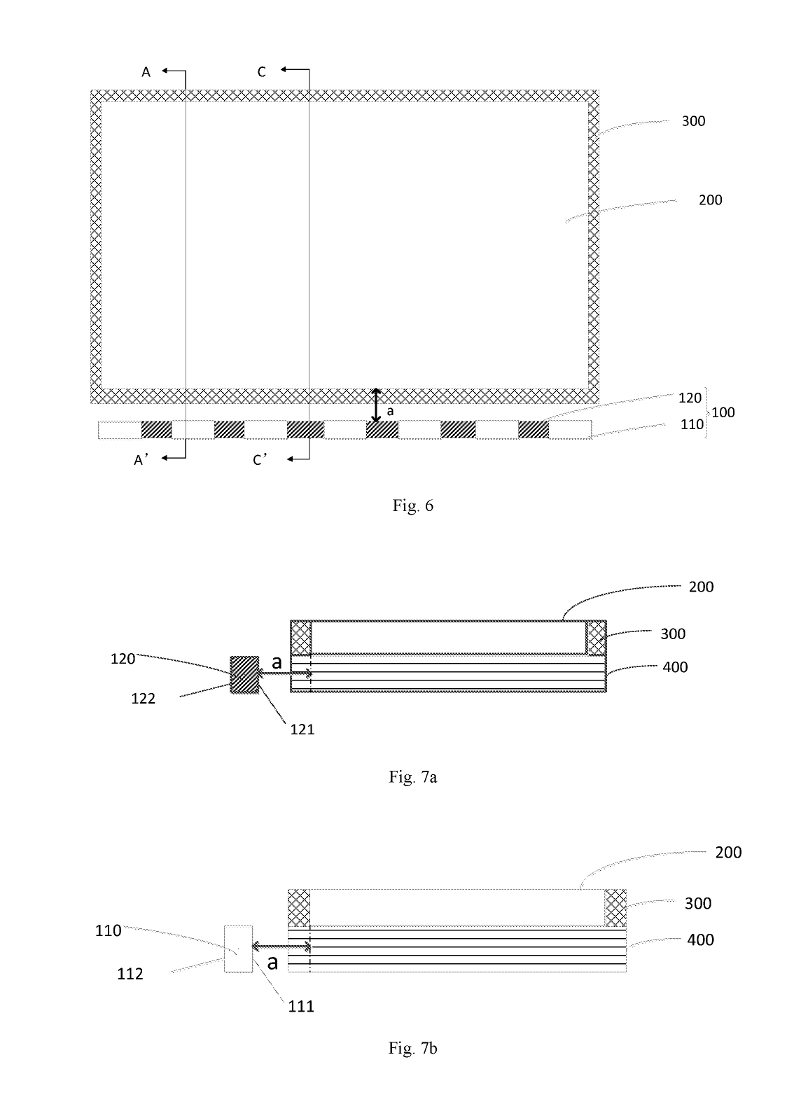

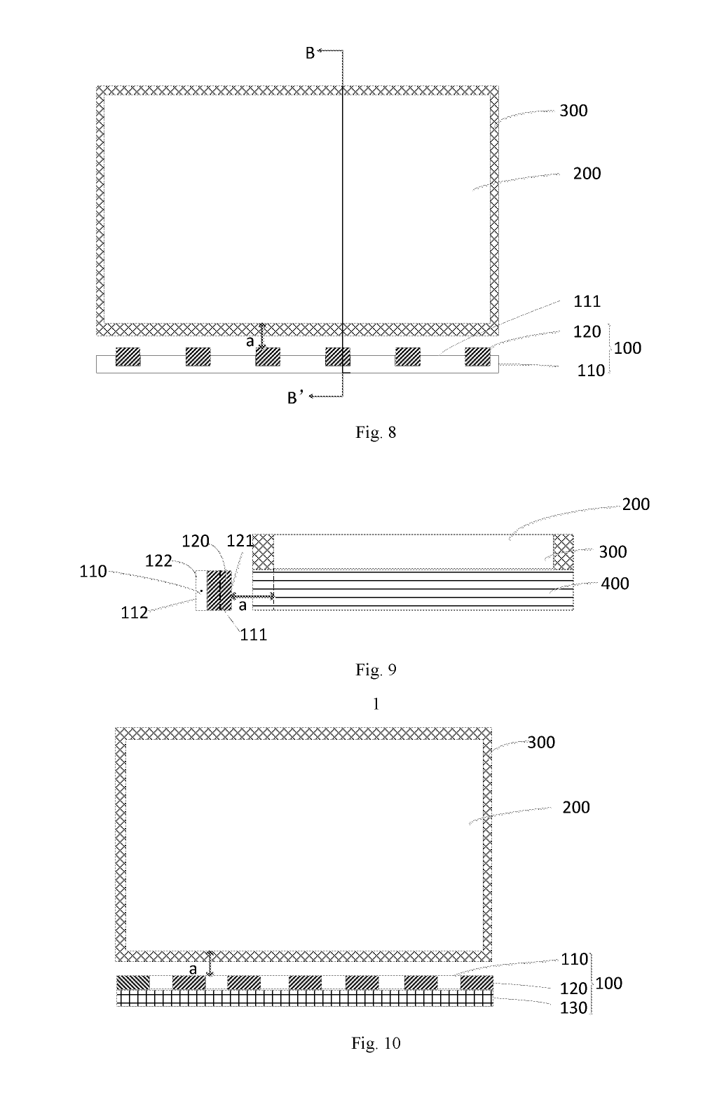

According to the embodiments of the present disclosure, the size of the opening is not particularly limited as long as the requirements can be satisfied, and those skilled in the art can flexibly select the size of the opening according to actual requirements. The size of the opening can be equal to or slightly larger than the size of the light emitting diode, which will not be described in detail herein; the shape of the opening is also not particularly limited as long as the requirements can be satisfied, and those skilled in the art can flexibly select the shape of the opening according to actual requirements. The shape of the opening can be the same as the shape of the light emitting diode, which will not be described in detail herein. In the embodiments shown in FIG. 3, FIG. 4 and FIG. 5, for example, the size of the opening 113 is slightly larger than that of the light emitting diode 120. In the embodiments shown in FIG. 6, FIG. 8 and FIG. 10, for example, the size of the opening is substantially equal to that of the light emitting diode 120.

In some embodiments, the number of the at least one opening is greater than or equal to 2, and the at least one opening is evenly distributed in the long side direction of the substrate. According to the embodiments of the present disclosure, the number of the openings is not particularly limited as long as the display requirements of the display device can be satisfied, and those skilled in the art can flexibly select the number of the openings according to actual requirements. According to the embodiments of the present disclosure, the distribution manner of the plurality of openings are not particularly limited as long as the requirements can be satisfied, and those skilled in the art can flexibly select the distribution manner according to actual requirements. For example, the distribution of the plurality of openings can be a uniform arrangement or a non-uniform arrangement; the distance between adjacent two openings is not particularly limited as long as the requirements can be satisfied, and those skilled in the art can flexibly select the distance between adjacent two openings according to actual requirements. According to an optional embodiment of the present disclosure, the plurality of openings are evenly distributed in the long side direction of the substrate. Thus, the structure of the backlight unit is simple and easily implemented. The backlight unit obtained by embedding light emitting diodes into the openings can effectively illuminate the light guide plate, thereby satisfying the display requirements of the display device, and the uniformity of light emitted from the light guide plate is improved.

In some embodiments, each opening is provided with one light emitting diode. According to the embodiments of the present disclosure, the number of the openings and the light emitting diodes can be the same or can be different as long as the requirements can be satisfied, and those skilled in the art can flexibly select the number of the openings and the light emitting diodes according to actual requirements. In some embodiments of the present disclosure, each opening is provided with one light emitting diode. In this way, the light emitting diodes are embedded in the openings, and the space occupation ratio of the thickness of the backlight unit can be significantly reduced.

According to the embodiments of the present disclosure, the relative position of the light emitting diode and the substrate is not particularly limited as long as the space occupation ratio of the thickness of the backlight unit can be effectively reduced, and those skilled in the art can flexibly select the relative position according to actual requirements. In some embodiments of the present disclosure, referring to FIG. 8 and FIG. 9, the light emitting surface 121 of the light emitting diode 120 is protruding with respect to the front surface 111 of the substrate 110. Thus, the space occupation ratio of the thickness of the backlight unit can be reduced, the distance between the backlight unit and the display area can be increased, and macroscopical light shadow or light leakage can be reduced. In other embodiments of the present disclosure, referring to FIG. 6-FIG. 7b, the light emitting surface 121 of the light emitting diode 120 is located in the same plane as the front surface 111 of the substrate 11. Thus, the space occupation ratio of the thickness of the backlight unit can be greatly reduced, the distance between the backlight unit and the display area can be increased, and macroscopical light shadow or light leakage can be significantly reduced.

According to an embodiment of the present disclosure, referring to FIG. 4 and FIG. 5, the surface 122 of the light emitting diode 120 opposite to the light emitting surface is fixedly connected with the back surface 112 of the substrate 110. In this way, the light emitting diode can be fixed on the substrate so that the light emitting diode can be firmly embedded in the substrate, and the fixed connection between the surface of the light emitting diode opposite to the light emitting surface and the back surface of the substrate will not affect the light emission of the light emitting diode. Meanwhile, the heat dissipation performance of the substrate can be improved, thereby improving the user experience, safety and reliability.

It should be noted that, the light emitting surface of the light emitting diode and the front surface of the substrate in the description herein refer to the surfaces facing the display area in actual use. The surface of the light emitting diode opposite to the light emitting surface and the back surface of the substrate refer to surfaces facing away from the display area in actual use.

According to the embodiments of the present disclosure, the manner of the fixed connection is not particularly limited as long as the light emitting diode and the substrate can be effectively connected, and those skilled in the art has the flexibility to select the manner of the fixed connection according to actual requirements. For example, the fixed connection manner can be, but is not limited to, binding, bonding, or soldering. Thus, the operation of connection is simple and easy to be implemented. The light emitting diode and the substrate can be effectively fixedly connected, and the light emitting diode is firmly embedded in the substrate.

According to the embodiments of the present disclosure, referring to FIG. 10, the backlight unit 100 further includes a protective layer 130 covering the back surface 112 of the substrate 110 and the surface 122 of the light emitting diode 120 opposite to the light emitting surface. Thus, the surface of the light emitting diode fixed to the substrate can be protected from being damaged, and the fixed connection between the light emitting diode and the substrate can be ensured, so that the light emitting diode can be firmly embedded in the substrate.

According to the embodiments of the present disclosure, the material for forming the protective layer is not particularly limited as long as it can protect the surface of the fixed connection between the light emitting diode and the substrate from being damaged, and those skilled in the art can flexibly select the material according to actual requirements. For example, the material for forming the protective layer can be, but is not limited to, photoresist, or polyimide, etc. Thus, the material is varied, the price is low, and the protection effect is improved.

In another embodiment of the present disclosure, the present disclosure provides a method for manufacturing a backlight unit for a display device. According to an embodiment of the present disclosure, the method includes: forming at least one opening in a substrate; and embedding a light emitting diode in the at least one opening. It is found that the space occupied by the backlight unit obtained by the above method is small. When the backlight unit is applied to a display device, the distance between the backlight unit and the display area of the display device can be effectively increased, thereby reducing light shadow or light leakage due to the insufficient incident distance of the backlight unit in the display device, improving the display quality of the display device, and improving the user's experience.

In some embodiments, the light emitting diode includes a light emitting surface and a surface opposite to the light emitting surface; the method further includes: arranging the light emitting surface and a front surface of the substrate in a same plane. In addition, in some embodiments, the method further includes: fixedly connecting the surface opposite to the light emitting surface to the back surface of the substrate. In some embodiments, the method further includes: arranging a protective layer covering the back surface of the substrate and the surface opposite to the light emitting surface. Thus, the operation is simple and easy to be implemented, and the light emitting diode can be firmly embedded in the substrate.

According to the embodiments of the present disclosure, the specific methods for forming openings, connecting the light emitting diode to the substrate, and forming the protective layer are not particularly limited, and those skilled in the art can flexibly select the specific methods according to actual requirements. For example, the method for forming openings includes, but is not limited to, etching and cutting, etc. The connecting method can include, but is not limited to, binding, bonding, or soldering, etc. The process for forming the protective layer includes, but is not limited to, coating, deposition, etc., which will not be described in detail herein.

According to the embodiments of the present disclosure, the backlight unit has the same structure, composition, and properties as the above backlight unit, which will not be described in detail herein.

In yet another embodiment of the present disclosure, the present disclosure provides a backlight module. According to the embodiments of the present disclosure, referring to FIG. 6 to FIG. 10, the backlight module includes the above backlight unit. It has been found that the space occupied by the thickness of the backlight module including the backlight unit is small, and when applied to a display device, the distance between the backlight unit in the backlight module and the display area of the display device is large. As a result, light shadow or light leakage due to the insufficient incident distance of the backlight unit is reduced, or the light emitting diode can be prevented from being damaged by impacts.

According to the embodiments of the present disclosure, the backlight module has the same structure, composition, and properties as the backlight unit as described above.

According to the embodiments of the present disclosure, there is no particular limitation on the installation position of the backlight unit when it is used as long as the requirements can be satisfied, and those skilled in the art can flexibly select the installation position of the backlight unit according to actual requirements. In some embodiments of the present disclosure, the backlight unit can be a side-light type backlight unit, and can also be a direct-type backlight unit (FIG. 6 to FIG. 10 only show the case of the side-light type). Thus, the display device including the backlight unit has a small frame or has no frame, providing a good appearance a better using effect, thereby improving the user's experience.

According to the embodiments of the present disclosure, the specific structure of the backlight module is not particularly limited. Besides the backlight unit in the disclosure, the backlight module includes the structures and components of a conventional backlight module. For example, the backlight module can further include a light guide plate, an upper prism sheet, a lower prism sheet, a diffusion sheet, a reflection sheet, a back adhesive, an iron part, a light-shielding film, and other components not described in detail herein.

In still another embodiment of the present disclosure, the present disclosure provides a display device. According to an embodiment of the present disclosure, the display device includes the backlight module. It has been found that the display device including the backlight module has high display quality, provides better user experience, and is suitable for market.

According to the embodiments of the present disclosure, the display device has the same structure, composition, and properties as the backlight module as described above.

According to the embodiments of the present disclosure, referring to FIG. 6 to FIG. 10, the distance β between the light emitting surface 121 of the light emitting diode 120 and the display area 200 of the display device is 3.5-3.7 mm. The distance between the light emitting diode and the display area can be set within the above range, and the light shadow or light leakage due to the insufficient incident distance of the backlight unit can thus be effectively reduced. Therefore, the display device including the backlight unit has a good display effect, and the user's experience can be improved. According to the embodiments of the present disclosure, the type of the display device is not particularly limited. For example, the display device can be, but is not limited to, cell phones, computers, televisions, wearable devices, etc. The specific structure of the display device is not particularly limited. Besides the backlight module in the disclosure, the display device includes the structures and components of a conventional display device, which will not be described in detail herein.

According to the embodiments of the present disclosure, in a common display device, the backlight unit is manufactured by directly attaching the light emitting diodes to the surface of the substrate, so that the thickness of the backlight unit is large, and the distance between the light emitting diodes and the display area is small. The small distance causes macroscopical light shadow and light leakage, and the display effect is relatively poor. The light emitting diodes are exposed so that they are vulnerable to damages caused by impacts. In the present disclosure, by embedding a light emitting diode in a substrate, the space occupation ratio of the thickness of the backlight unit can be effectively reduced. When applied to a display device, the distance between the backlight unit and the display area of the display device can be effectively increased, thereby reducing light shadow or light leakage due to insufficient incident distance of the backlight unit in the display device and improving the display quality. By disposing the surface of the light emitting diode facing the display area and the surface of the substrate facing the display area in the same plane, the light emitting diode can be prevented from being damaged by impacts.

In the description of the present disclosure, it should be understood that the orientation or positional relationship indicated by terms “center”, “longitudinal”, “transverse”, “length”, “width”, “thickness”, “upper”, “lower”, “front”, “back”, “left”, “right”, “vertical”, “horizontal”, “top”, “bottom”, “inner”, “outer”, “clockwise”, “counterclockwise”, “axial”, “radial”, “circumferential”, etc. is based on the orientation or positional relationship shown in the drawings, and is merely for convenience of describing the present disclosure, but does not indicate or suggest the indicated device or element must have a particular orientation, be constructed and operated in a particular orientation, and therefore should not be construed as limiting the present disclosure.

Furthermore, the terms “first” and “second” are used for descriptive purposes only, and are not to be construed as indicating or implying relative importance or implicitly indicating the number of indicated technical features. Thus, features defined as “first”, “second” may explicitly or implicitly include one or more of the features. In the description of the present disclosure, the meaning of “plurality” is two or more than two unless it is specifically defined otherwise.

In this disclosure, the terms “install”, “attach”, “connect”, “fix”, etc. should be understood broadly unless specifically stated and defined otherwise. For example, it can be a fixed connection, a detachable connection, or an integral connection; it can be a mechanical connection, or an electrical connection as well; it can be connected directly, or connected indirectly through an intermediary; it can be an internal connection of two elements or an interaction of two elements. Those skilled in the art can understand the specific meanings of the above terms in the present disclosure according to specific circumstances.

In the present disclosure, unless specifically stated and defined otherwise, the first feature “on” or “under” the second feature can be that the first and second features contact directly, or that the first and second features are contact indirectly via an intermediary. Moreover, the first feature “over” or “above” the second feature can be that the first feature directly above or diagonally above the second feature, or merely indicate that the first feature is higher in height than the second feature. The first feature “below” or “under” the second feature can be that the first feature directly below or diagonally below the second feature, or merely indicate that the first feature is lower in height than the second feature.

In the description of the present specification, the description referring to the terms “an embodiment”, “some embodiments”, “an example”, “a specific example”, or “some examples” or the like means a specific feature, structures, materials, or characters described in conjunction with the embodiment or example are included in at least one embodiment or example of the present disclosure. In this specification, the schematic expression of the above terms does not necessarily have to refer to the same embodiment or example. Furthermore, the specific features, structures, materials, or characteristics described can be combined in any suitable manner in any one or more of the embodiments or examples. In addition, those skilled in the art can combine the different embodiments or examples described in this specification and features of different embodiments or examples without conflicting with each other.

Although embodiments of the present disclosure have been shown and described above, it will be understood that the above embodiments are exemplary and not to be construed as limiting the present disclosure, and that those skilled in the art can make modifications, substitutions and variations within the scope of the present disclosure.

What is claimed is:

1. A backlight unit for a display device, comprising:
a substrate on which at least one opening is disposed;
a light emitting diode embedded in the at least one opening.

2. The backlight unit according to claim 1, wherein the number of the at least one opening is greater than or equal to 2, and the at least one opening is evenly distributed in a long side direction of the substrate.

3. The backlight unit according to claim 2, wherein each opening is provided with one light emitting diode.

4. The backlight unit according to claim 1, wherein the light emitting diode comprises a light emitting surface and a surface opposite to the light emitting surface; wherein the light emitting surface and a front surface of the substrate are located in a same plane.

5. The backlight unit according to claim 1, wherein the light emitting diode comprises a light emitting surface and a surface opposite to the light emitting surface; wherein the surface opposite to the light emitting surface is fixedly connected to a back surface of the substrate.

6. The backlight unit according to claim 5, further comprising:
a protective layer covering the back surface of the substrate and the surface opposite to the light emitting surface.

7. A method for manufacturing a backlight unit for a display device, comprising:
forming at least one opening in a substrate; and
embedding a light emitting diode in the at least one opening.

8. The method according to claim 7, wherein the light emitting diode comprises a light emitting surface and a surface opposite to the light emitting surface; the method further comprising:
arranging the light emitting surface and a front surface of the substrate in a same plane.

9. The method according to claim 7, wherein the light emitting diode comprises a light emitting surface and a surface opposite to the light emitting surface; the method further comprising:
fixedly connecting the surface opposite to the light emitting surface to a back surface of the substrate.

10. The method according to claim 9, further comprising:
arranging a protective layer covering the back surface of the substrate and the surface opposite to the light emitting surface.

11. A backlight module, comprising the backlight unit according to claim 1.

12. The backlight module according to claim 11, wherein the number of the at least one opening is greater than or equal to 2, and the at least one opening is evenly distributed in a long side direction of the substrate.

13. The backlight module according to claim 12, wherein each of the at least one opening is provided with one light emitting diode.

14. The backlight module according to claim 11, wherein the light emitting diode comprises a light emitting surface and a surface opposite to the light emitting surface; the light emitting surface and a front surface of the substrate are located in a same plane.

15. The backlight module according to claim 11, wherein the light emitting diode comprises a light emitting surface and a surface opposite to the light emitting surface, and the surface opposite to the light emitting surface is fixedly connected to a back surface of the substrate.

16. The backlight module according to claim 15, further comprising:
a protective layer covering the back surface of the substrate and the surface opposite to the light emitting surface.

17. A display device, comprising the backlight module of claim 11.

18. The display device according to claim 17, wherein a distance between a light emitting surface of the light emitting diode of the backlight module and a display area of the display device ranges from 3.5 to 3.7 mm.

19. The display device according to claim 17, wherein the light emitting diode comprises a light emitting surface and a surface opposite to the light emitting surface; the light emitting surface and a front surface of the substrate are located in a same plane.

20. The display device according to claim 17, wherein the light emitting diode comprises a light emitting surface and a surface opposite to the light emitting surface, and the surface opposite to the light emitting surface is fixedly connected to a back surface of the substrate.
